(19) United States
(12) Patent Application Publication
(10) Pub. No.: US 2025/0105057 A1
(43) Pub. Date: Mar. 27, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Shao-Kuan Lee, Kaohsiung City (TW); Tzu-Hui Wei, Zhubei City (TW); Cheng-Hsiung Tsai, Miaoli County (TW); Chieh-Han Wu, Kaohsiung City (TW); Yu-Hao Yeh, Hsinchu City (TW)

(73) Assignee: Taiwan Semiconductor Manufacturing Company, Ltd., Hsinchu (TW)

(21) Appl. No.: 18/472,243

(22) Filed: Sep. 22, 2023

(51) Int. Cl. H01L 21/768; H01L 23/535

(52) U.S. Cl. CPC H01L 21/76844; H01L 21/76805; H01L 21/76829; H01L 21/76895; H01L 23/535

(57) ABSTRACT

An interconnect structure includes a first conductive feature, a first dielectric layer a first etch stop layer, a second etch stop layer, a second dielectric layer, and a second conductive feature. The first etch stop layer is disposed over the first conductive feature and the first dielectric layer. The second etch stop layer is disposed on the first etch stop layer. The second dielectric layer is disposed on the second etch stop layer. The second conductive feature includes a first conductive layer and a first barrier layer. The first conductive layer extends through the second dielectric layer, the second and the first etch stop layers to contact to the first conductive feature. The first barrier layer is sandwiched between the first conductive layer and the second dielectric layer, the first conductive layer and the second etch stop layer, and between the first conductive layer and the first etch stop layer.

### BACKGROUND

As the density of semiconductor devices increases and as the size of circuit elements becomes smaller, resistance-capacitance (RC) delay time increasingly affects integrated circuit performance. Low-k dielectric materials, therefore, are used to reduce the RC delay. Low-k dielectric materials are particularly useful as inter-layer dielectrics and inter-metal dielectrics.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are cross-sectional views illustrating various stages of a method of fabricating a semiconductor device in accordance with some embodiment of the disclosure.

FIG. 2A to FIG. 2H are cross-sectional views illustrating various stages of a method of fabricating a semiconductor device in accordance with some alternative embodiment of the disclosure.

FIG. 3 is a cross-sectional view illustrating a semiconductor device in accordance with some alternative embodiments of the disclosure.

FIG. 4A to FIG. 4G are cross-sectional views illustrating various stages of a method of fabricating a semiconductor device in accordance with some alternative embodiment of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

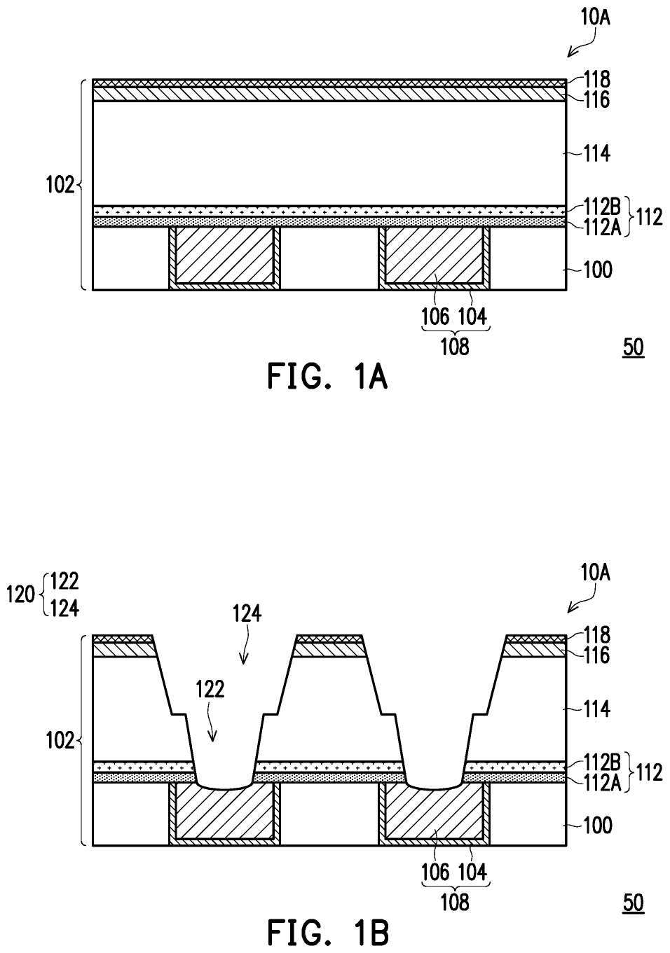

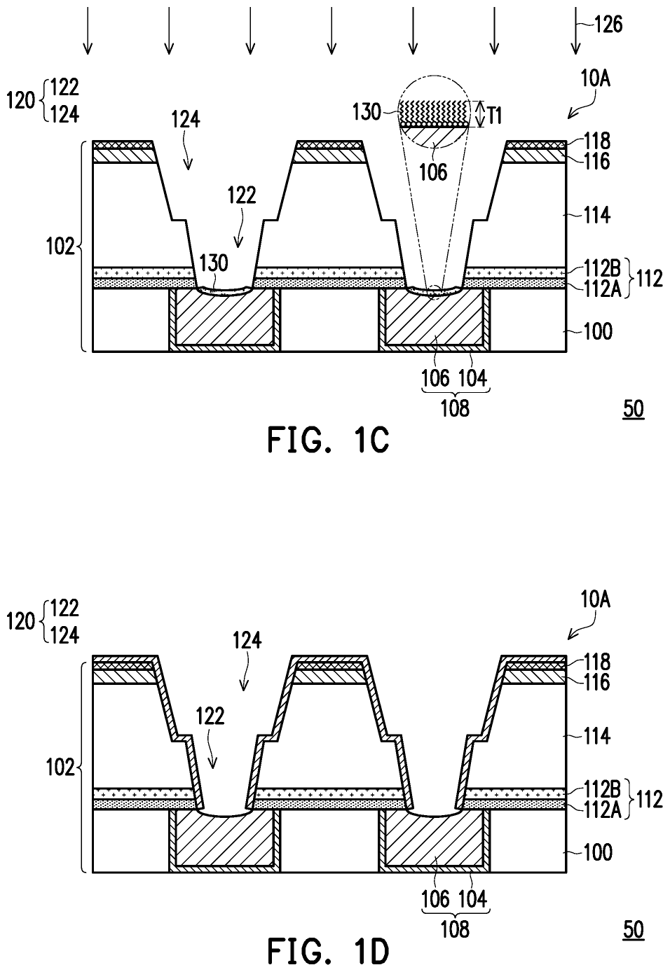

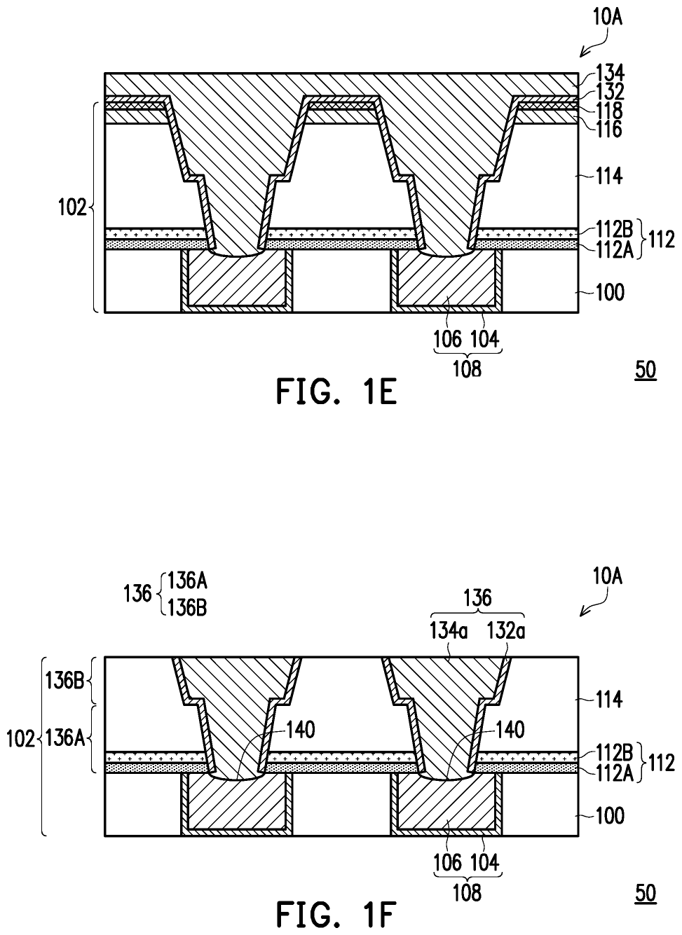

FIG. 1A to FIG. 1F are cross-sectional views illustrating various stages of a method of fabricating a semiconductor device 10A in accordance with some embodiment of the disclosure.

Referring to FIG. 1A, a substrate 50 is provided. The substrate 50 may be a semiconductor substrate, such as a bulk semiconductor substrate, a semiconductor-on-insulator (SOI) substrate, or the like. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate, may also be used.

In some embodiments, the substrate 50 includes a crystalline silicon substrate (e.g., wafer). In some alternative embodiments, the semiconductor substrate 50 is made of some other suitable elemental semiconductor, such as diamond or germanium; a suitable compound semiconductor, such as gallium arsenide, silicon carbide, gallium phosphide, indium phosphide, indium arsenide, and/or indium antimonide; or a suitable alloy semiconductor, such as SiGe, GaAsP, AlInAs, AlGaAs, GaInAs, GaInP, and/or GaInAsP. The substrate 50 may include various doped regions depending on design requirements (e.g., p-type semiconductor substrate or n-type semiconductor substrate). The doped regions may be doped with p-type or n-type dopants. For example, the doped regions may be doped with p-type dopants, such as boron (B) or BF₂; n-type dopants, such as phosphorus (P) or arsenic (As); and/or a combination thereof. The dopant concentration in various doped regions may be different.

In some embodiments, depending on product design requirements, a device layer (not shown) may be formed on the substrate 50. The device layer may include a device such as an active device (e.g., a transistor or the like) and/or a passive device (e.g., a capacitor, an inductor, or the like). The transistor may be a planar metal-oxide-semiconductor field-effect transistor (MOSFET), a FinFET, or a Gate All Around (GAA) transistor. Furthermore, the device layer may further include a dielectric layer, and the device may be disposed in the dielectric layer. In some embodiments, the material of the dielectric layer includes silicon oxide (SiOₓ), silicon nitride (SiNₓ), silicon oxynitride (SiON), phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some alternative embodiments, the material of the dielectric layer includes a low-k dielectric material. The dielectric layer may include one or more dielectric materials and/or one or more dielectric layers. In some embodiments, the dielectric layer is formed to a suitable thickness by Flowable Chemical Vapor Deposition (FCVD), thermal chemical vapor deposition (CVD), High Density Plasma Chemical Vapor Deposition (HDPCVD), Sub Atmospheric Chemical Vapor Deposition (SACVD), spin-on, sputtering, or other suitable methods. Besides, the device layer may further include interconnect to electrically connect to the device.

Referring to FIG. 1A, metallization layers of an interconnect structure 102 are formed over the device layer and designed to connect to the active device to form functional circuitry for the design. In some embodiments, the metallization layers are formed of alternating layers of dielectric and conductive material and may be formed through any suitable process (such as deposition, damascene, dual damascene, etc.).

In some embodiments, there may be one to four layers of metallization separated from each other by at least one dielectric layer 100, but the precise number of metallization layers is dependent upon the design. The dielectric layer 100 may be referred to as an interlayer dielectric layer (ILD). In some embodiments, the material of the at least one dielectric layer 100 includes silicon oxide (SiOₓ), silicon nitride (SiNₓ), silicon oxynitride (SiON), phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some alternative embodiments, the material of the dielectric layer 100 includes a low-k dielectric material. The dielectric layer 100 may include one or more dielectric materials and/or one or more dielectric layers. In some embodiments, the dielectric layer 100 is formed to a suitable thickness by Flowable Chemical Vapor Deposition (FCVD), thermal chemical vapor deposition (CVD), High Density Plasma Chemical Vapor Deposition (HDPCVD), Sub Atmospheric Chemical Vapor Deposition (SACVD), spin-on, sputtering, or other suitable methods.

Conductive features 108 may be formed in the dielectric layer 100 or over the metallization layers, and use as region to which an interconnect will make physical and electrical connection. The sidewalls of the conductive features 108 may be surrounded by the dielectric layer 100. The conductive features 108 may be contacts, vias, conductive lines, or a combination thereof. In some embodiments, the conductive features 108 may include a conductive layer 106 and a barrier layer 104 formed by using, e.g., a damascene, or dual damascene process, whereby openings are formed within the metallization layers, the openings are filled and/or overfilled with the conductive layer 106 and the barrier layer 104, and a planarization process is performed to embed the conductive layer 106 and the barrier layer 104 within the metallization layers. The material of the barrier layer 104 may include tantalum (Ta), tantalum nitride (TaN), titanium (Ti), titanium nitride (TiN) or a combination thereof. The barrier layer 104 may be formed by, for example, PVD or ALD. The material of the conductive layer 106 may include copper (Cu), ruthenium (Ru), cobalt (Co), or a combination thereof. The conductive layer 106 may be formed by a plating process, CVD,
PECVD, PVD, a combination thereof, or the like. However, any suitable process may be used to form the conductive features 108.

An etch stop stack 112 may be formed over the substrate 50. In some embodiments, the etch stop stack 112 is formed on the conductive features 108 and the dielectric layer 100. The etch stop stack 112 may be a multi-layered structure, such as a bi-layer structure, a tri-layer structure, or a four-layer structure etc.

Referring to FIG. 1A, for example, the etch stop stack 112 is provided with a bi-layer structure. The etch stop stack 112 includes a first etch stop layer 112A and a second etch stop layer 112B. The first etch stop layer 112A and the second etch stop layer 112B of the etch stop stack 112 are formed with different materials with different etching selectivity. The first etch stop layer 112A includes a Group IV element-doped layer to provide more hydrophobic surfaces of the first etch stop layer 112A. The Group IV element-doped layer includes a compound having carbon atom, semiconductor atom such as silicon atom, or a combination thereof. The material of the Group IV element-doped layer may be carbon-doped metal oxide, carbon-doped metal nitride, metal carbide, semiconductor carbide, semiconductor carbon nitride, semiconductor carbon oxide, or a combination thereof. The material of the Group IV element-doped layer may include AlOₓC_{y}, AlₓC_{y}, AlₓC_{y}N_{z}, TiOₓC_{y}, TiₓC_{y}, TiₓC_{y}N_{z}, WOₓC_{y}, WₓC_{y}, WₓC_{y}N_{z}, SiOₓC_{y}, SiC, SiₓC_{y}N_{z} or a combination thereof. The second etch stop layer 112B of the etch stop stack 112 includes silicon nitride (SiₓN_{y}), SiCₓO_{y} or SiOₓN_{y}. The first etch stop layer 112A and the second etch stop layer 112B may be formed by plasma enhanced chemical vapor deposition (PECVD), plasma enhanced atomic layer deposition (PEALD), CVD, thermal ALD, physical vapor deposition (PVD), a combination thereof, or the like. In some embodiments, the thickness of the thickness of the first etch stop layer 112A or the second etch stop layer 112B ranges from 10 angstroms (Å) to 70 Å.

Referring to FIG. 1A, a dielectric layer 114 is formed over the substrate 50. In some embodiments, the dielectric layer 114 may be formed on the etch stop stack 112. The etch stop stack 112 may be disposed between the substrate 50 and the dielectric layer 114. The dielectric constant of the dielectric layer 114 is lower than the dielectric constant of each layer of the etch stop stack 112. The dielectric constant of the dielectric layer 114 may be less than 3.5. For example, the dielectric constant of the dielectric layer 114 ranges from 2.6 to 3.3, such as 2.7, 2.8, 2.9, 3.0, 3.1, or 3.2, including any range between any two of the preceding values. The dielectric layer 114 may be referred to as a low-k dielectric layer. In some embodiments, the dielectric layer 114 includes a porous dielectric material. In some embodiments, the dielectric layer 114 includes elements such as Si, O, C, N and/or H. For example, the dielectric layer 114 includes SiOCH, SiOC, SiOCN or a combination thereof. In some embodiments, the dielectric layer 114 includes BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. The dielectric layer 114 may include one or more dielectric materials and/or one or more dielectric layers. The dielectric layer 114 may be formed to a suitable thickness by PECVD, PEALD, spin coating, a combination thereof, or the like.

A cap layer 116 is formed on the dielectric layer 114. The dielectric constant of the cap layer 116 may range from 3.0 to 4.2 including any range between any two of the preceding values. The material of the cap layer 116 may include SiₓO_{y}, SiOC, or SiCOH. The cap layer 116 may include one or more dielectric materials and/or one or more dielectric layers. The cap layer 116 may be formed by PECVD, PEALD, thermal CVD, thermal ALD, PVD, spin coating, a combination thereof, or the like. In some embodiments, the cap layer 116 is silicon oxide formed by PECVD process employing tetraethylorthosilicate (TEOS) as a precursor gas. In some embodiments, the dielectric constant of the cap layer 116 is greater than the dielectric constant of the dielectric layer 114. In some embodiments, the dielectric layer 114 and the cap layer 116 include the same elements, but the atom content of each element is different. In some alternative embodiments, at least one element of the dielectric layer 114 is different from the elements included in the cap layer 116.

Referring to FIG. 1A, a hard mask layer 118 may be formed on the cap layer 116. In some embodiments, the material of the hard mask layer 118 includes silicon oxide, silicon nitride, silicon carbide, amorphous carbon, a photoresist material, tungsten-doped carbon (WDC), titanium nitride (TiN) a suitable hard mask material, or a combination thereof. In some embodiments, the hard mask layer 118 may be a single-layered structure. In some alternative embodiments, the hard mask layer 118 may be a multi-layered structure.

As illustrated in FIG. 1B, patterning processes may be performed, thereby forming openings 120 in the hard mask layer 118, the cap layer 116, the dielectric layer 114, and the etch stop stack 112. The openings 120 each may expose the conductive feature 108. In some embodiments, the openings 120 are dual damascene openings. The dual damascene openings include lower via-hole sections 122 and upper trench sections 124 on the lower via-hole section 122. In some embodiments, a portion of the conductive features 108 are removed, and recesses are formed on the conductive features 108, so that the bottom surfaces of the openings 120 is lower than the bottom surface of the first etch stop layer 112A. The openings 120 may be formed by “via-first” patterning process, “trench-first” patterning process, or double patterning process. The upper trench section 124 and the lower via-hole section 122 may be formed using photolithography with masking technologies and anisotropic etch operations (e.g., plasma etching or reactive ion etching).

Referring to FIG. 1C, after the openings 120 are formed, a backing process is performed, such as a single wafer backing (SWB) process. Furthermore, an active preclean process (APC) is performed so as to reduce the metal oxide, such as copper oxide, formed on the conductive feature 108 to metal, such as copper. The active preclean process may be performed by using a plasma treatment process. The plasma treatment process may include plasma reaction gases such as He, Ar, NH₃, the like, or a combination thereof.

A surface treatment 126 is performed on the conductive features 108 exposed by the openings 120 to selectively modify top surfaces of the conductive features 108 to increase the difference in surface energy between the conductive features 108 and the etch stop stack 112, between the conductive features 108 and the dielectric layer 114, between the conductive features 108 and the cap layer 116, and between the conductive features 108 and the hard mask layer 118. In some embodiments, the surface treatment 126 is performed to provide treated surfaces of the conductive features 108 with high hydrophobicity or super hydrophobicity. The hydrophobicity of the treated surfaces of the conductive features 108 is greater than the hydrophobicity of the more hydrophobic surfaces of the first etch stop layer 112A. For example, the surface treatment 126 may be performed by a method described as follows.

Inhibitor portions 130 are selectively formed on the conductive features 108 exposed by the openings 120. The inhibitor portions 130 may be referred to as blocking layers that block the surfaces of the conductive features 108 to prevent the subsequently formed barrier layer 132 (shown in FIG. 1D) from being deposited on the surfaces of the conductive features 108.

In an embodiment in which the conductive features 108 are formed of metal such as copper, the inhibitor portions 130 are formed of an organic material which may be reacted with or adsorbed on metal surfaces of the conductive features 108. The organic material may be a self-assembled monolayer (SAM) for surface modification of the conductive features 108, for example. The SAM may be a molecular assembly organized into ordered domains on the exposed metal surfaces of the conductive features 108. Each molecule of the SAM may include a head group and a tail, where the head group anchors the molecule to the metal surfaces of the conductive features 108 and the tail prevents the barrier layer 132 from being deposited on the metal surfaces of the conductive features 108.

In some embodiments, the head group is a metallophilic head group that anchors to the conductive features 108. In an embodiment, the metallophilic head group of the molecule comprises Group V elements and Group VI elements, such as nitrogen atom (N), oxygen atom (O), sulfur atom(S), phosphorous atom (P), or the like.

According to embodiments of the disclosure, the tail of the molecule that form the inhibitor portions 130 is a metallophobic alkyl tail. The metallophobic alkyl tail has, for example, alkyl chain with a large molecular size or a long carbon chain to prevent the barrier layer 132 from being deposed on surface thereof. The tail of the SAM provides a high hydrophobic surface which may prevent the barrier layer 132 from being deposited on its surface. For example, the inhibitor portions 130 may be formed of molecules selected from, but not limited to, benzotriazole, 1,2,3-triazole, 2-mercaptobenzimidazole, benzothiazol, methimazole, pentaerythritol phosphate (PEPA), 4-Methyl-1H-benzotriazole, 5,6-dimethyl-1H-benzotriazole, octadecylphosphonic acid, and a combination thereof. The inhibitor portions 130 may have a thickness TI of approximately 3Å to 30Å. The inhibitor portions 130 may be deposited by spin-on coating, CVD, ALD, a combination thereof, or the like.

In an embodiment in which the first etch stop layer 112A is formed of Group IV element-doped layer, the inhibitor portions 130 are formed of an organic material which may not be reacted with or adsorbed on hydrophobic surfaces of the first etch stop layer 112A. Therefore, the inhibitor portions 130 may be selectively formed on the conductive features 108 instead of the first etch stop layer 112A.

Referring to FIG. 1D, a barrier layer 132 may be formed in the openings 120. The inhibitor portions 130 provide high hydrophobic surfaces, and the first etch stop layer 112A provide more hydrophobic surfaces. The hydrophobicity of the high hydrophobic surfaces is greater than the hydrophobicity of the more hydrophobic surfaces. Therefore, the inhibitor portions 130 may prevent the barrier layer 132 from depositing on its surface. The barrier layer 132 may be formed on the sidewalls of the hard mask layer 118, the cap layer, the dielectric layer 114, the second etch stop layer 112B and the first etch stop layer 112A.

Because the inhibitor portions 130 is not formed on the sidewalls of the first etch stop layer 112A, the barrier layer 132 may be formed along the sidewalls and the bottoms of the trench sections 124, and the sidewalls of the via sections 122. In some embodiments, the barrier layer 132 is conformally and continuously formed from the top sidewalls of the hard mask layer 118 to the bottom sidewalls of the first etch stop layer 112A. The entire of sidewalls of the first etch stop layer 112A and the second etch stop layer 112B are wrapped by the barrier layer 132. The material of the barrier layer 132 may include tantalum (Ta), tantalum nitride (TaN), titanium (Ti), titanium nitride (TiN) or a combination thereof. The barrier layer 132 may be formed by, for example, PVD or ALD. The inhibitor portions 130 are then removed to expose the top surface of the conductive features 108. In some embodiments, the removal of the inhibitor portions 130 is by a plasm process including H₂, although any suitable removal process may be used.

Referring to FIG. 1E, a conductive layer 134 may be formed in the openings 120. The conductive layer 134 is formed on the barrier layer 132 and on the conductive features 108. The material of the conductive layer 134 may include copper (Cu), ruthenium (Ru), cobalt (Co), or a combination thereof. The conductive layer 134 may be formed by a plating process, CVD, PECVD, PVD, a combination thereof, or the like. The conductive material may be formed by first depositing a seed layer (not shown) and then electroplating copper onto the seed layer, filling and overfilling the openings 120.

Referring to FIG. 1F, once the openings 120 have been filled, excess barrier layer 132 and excess conductive layer 134 outside of the openings 120 are removed to form a barrier layer 132a and a conductive layer 134a, thereby forming conductive features 136. In some embodiments, the removal of excess barrier layer 132 and excess conductive material 134 is by a chemical mechanical polishing (CMP), although any suitable removal process may be used. In some embodiments, the hard mask layer 118 and the cap layer 116 are removed in the above CMP process. Although a method of forming the conductive layer 134a and the barrier layer 132a is described by taking the above method as an example, the disclosure is not limited thereto. In some embodiments, a grinding process is performed instead of the mentioned polishing process. In some embodiments, an etching back process may be performed in combination with the mentioned polishing or grinding process.

In some embodiments, the conductive features 136 are dual damascene interconnects including conductive lines 136B and vias 136A below the conductive lines 136B. The sidewalls and the bottoms of the conductive layer 134a of the conductive lines 136B are wrapped by the barrier layer 132a. The sidewalls of the conductive layer 134a of the vias 136A are wrapped by the barrier layer 132a. The bottom surfaces of the conductive layer 134a of the vias 136A are electrically connected to and in physical contact with the top surfaces of the conductive features 108. Interfaces 140 between bottom surfaces of the conductive layer 134a of the vias 136A and a top surface of the conductive feature 108 are free of the barrier layer 132a.

The conductive layer 134a is disposed in and extends through the dielectric layer 114, and the etch stop stack 112. The barrier layer 132a is sandwiched between the conductive layer 134a and the dielectric layer 114, between the conductive layer 134a and the second etch stop layer 112B, and between the conductive layer 134a and the first etch stop layer 112A. Therefore, the sidewalls of the conductive layer 134a may be separated from the dielectric layer 114, the second etch stop layer 112B and the first etch stop layer 112A by the barrier layer 132a.

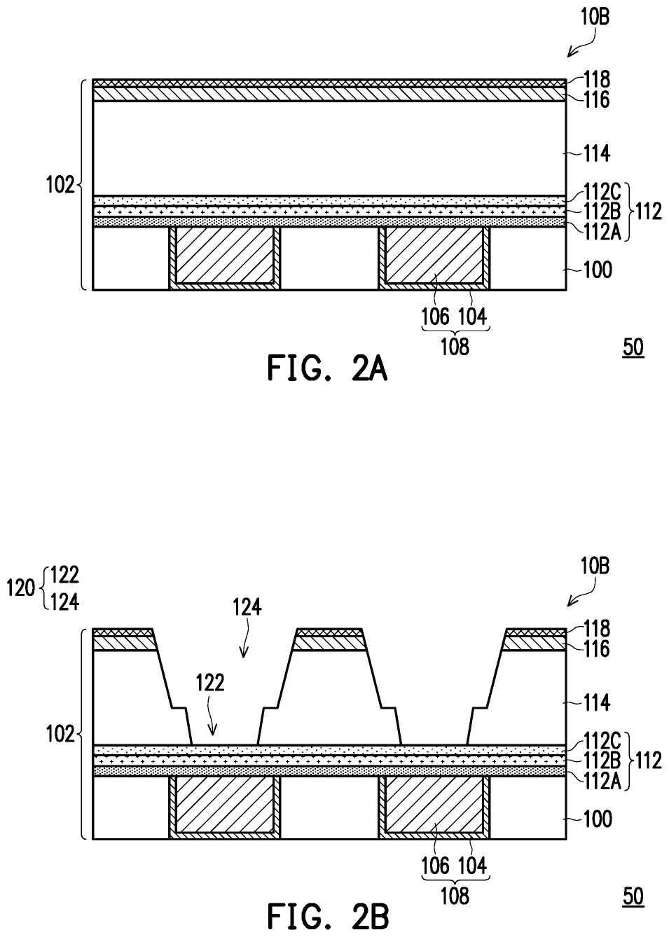

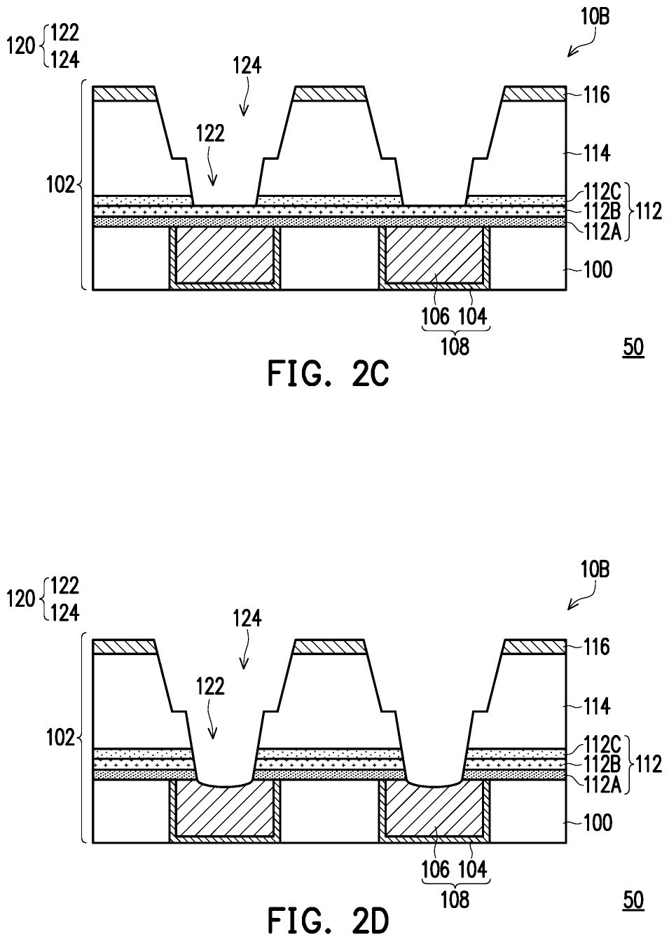

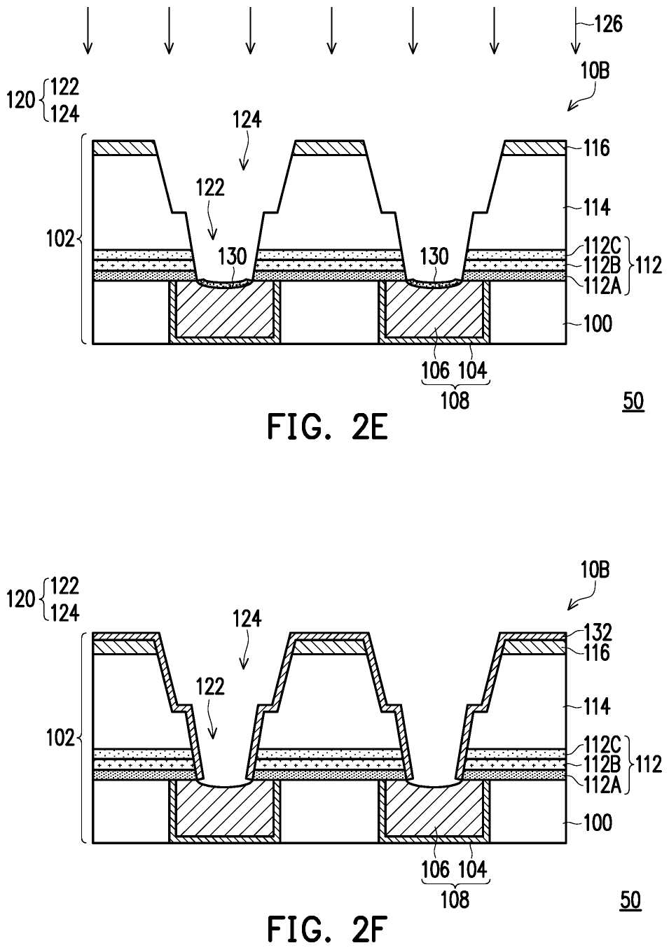

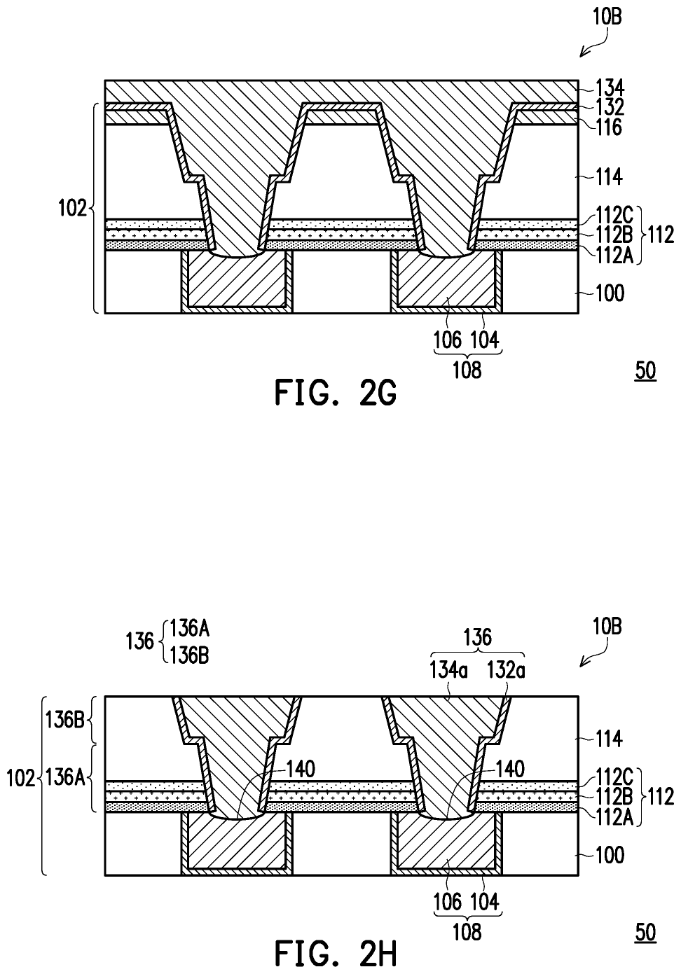

FIG. 2A to FIG. 2H are cross-sectional views illustrating various stages of a method of fabricating a semiconductor device 10B in accordance with some alternative embodiment of the disclosure. The semiconductor device 10B in FIG. 2H is similar to the semiconductor device 10A in FIG. 1D, so similar elements are denoted by the same reference numeral and the detailed descriptions thereof are omitted herein.

Referring to FIG. 2A, an etch stop structure 212 of the semiconductor device 10B is formed over the conductive features 108 and the interlayer dielectric layer (ILD) 100. The etch stop structure 212 is provided with a tri-layer structure. The etch stop stack 112 includes a first etch stop layer 112A, a second etch stop layer 112B and a third etch stop layer 112C. The third etch stop layer 112C is provided on the second etch stop layer 112B. The third etch stop layer 112C and the second etch stop layer 112B of the etch stop structure 212 are formed with different materials with different etching selectivity. The third etch stop layer 112C and the first etch stop layer 112A of the etch stop structure 212 are formed with a same material or different materials with different etching selectivity.

The third etch stop layer 112C includes a Group IV element-doped layer. The Group IV element-doped layer may be a compound including carbon atom or semiconductor atom such as silicon atom. The material of the Group IV element-doped layer may be carbon-doped metal oxide, carbon-doped metal nitride, metal carbide, semiconductor carbide, semiconductor carbon nitride, semiconductor carbon oxide, or a combination thereof. The material of the Group IV element-doped layer may include AlOₓC_{y}, AlₓC_{y}, AlₓC_{y}N_{z}, TiOₓC_{y}, TiₓC_{y}, TiₓC_{y}N_{z}, WOₓC_{y}, WₓC_{y}, WₓC_{y}N_{z}, SiOₓC_{y}, SiC, SiₓC_{y}N_{z}, or a combination thereof. The third etch stop layer 112C may be formed by plasma enhanced chemical vapor deposition (PECVD), plasma enhanced atomic layer deposition (PEALD), CVD, thermal ALD, physical vapor deposition (PVD), a combination thereof, or the like. In some embodiments, the thickness of the thickness of the third etch stop layer 112C ranges from 10 angstroms (Å) to 70 Å.

Referring to FIG. 2B, after the dielectric layer 114, the cap layer 116, and the hard mask layer 118 are formed over the etch stop structure 212, a patterning process may be performed to the hard mask layer 118, the cap layer 116, and the dielectric layer 114 by using the third etch stop layer 112C as an etch stop layer, thereby forming openings 120 in the hard mask layer 118, the cap layer 116, and the dielectric layer 114. The openings 120 each may expose the third etch stop layer 112C. In some embodiments, the openings 120 are dual damascene openings. In some embodiments, the openings 120 are dual damascene openings. The dual damascene openings include lower via-hole sections 122 and upper trench sections 124 on the lower via-hole section 122. The openings 120 may be formed by “via-first” patterning process, “trench-first” patterning process, or double patterning process. The upper trench section 124 and the lower via-hole section 122 may be formed using photolithography with masking technologies and anisotropic etch operations (e.g., plasma etching or reactive ion etching).

Referring to FIG. 2C, the hard mask layer 118 and the third etch stop layer 112C exposed by the openings 120 are removed to expose the cap layer 116 and the second etch stop layer 112B. In some embodiments, the removal of the hard mask layer 118 and a portion of the third etch stop layer 112C is by isotropic etch operations (e.g., wet etching) although any suitable removal process may be used.

Referring to FIG. 2D, the second etch stop layer 112B and the first etch stop layer 112A exposed by the openings 120 are removed to expose the conductive features 108 by using the cap layer 116 as an etch mask layer. In some embodiments, the removal of a portion of the second etch stop layer 112B and the first etch stop layer 112A is by anisotropic etch operations (e.g., plasma etching or reactive ion etching), and isotropic etch operations (e.g., wet etching), although any suitable removal process may be used.

Referring to FIG. 2E, after a backing process and an active preclean process (APC) are performed, a surface treatment 126 is performed on the conductive features 108 exposed by the openings 120 to selectively modify top surfaces of the conductive features 108 to increase the difference in surface energy between the conductive features 108 and the etch stop structure 212, between the conductive features 108 and the dielectric layer 114, and between the conductive features 108 and the cap layer 116.

In some embodiments, the surface treatment 126 is performed to provide treated surfaces of the conductive features 108 with high hydrophobicity or super hydrophobicity. The hydrophobicity of the treated surfaces of the conductive features 108 is greater than the hydrophobicity of the more hydrophobic surfaces of the first etch stop layer 112A. The surface treatment 126 may be performed by selectively forming inhibitor portions 130 on the conductive features 108 described as above.

Referring to FIG. 2F, a barrier layer 132 may be formed in the openings 120. The hydrophobicity of the high hydrophobic surfaces of the inhibitor portions 130 is greater than the hydrophobicity of the more hydrophobic surfaces of the first etch stop layer 112A. Therefore, the inhibitor portions 130 may prevent the barrier layer 132 from depositing on its surface. The barrier layer 132 may be formed on the sidewalls of the cap layer, the dielectric layer 114, the third etch stop layer 112C, the second etch stop layer 112B and the first etch stop layer 112A.

Referring to FIGS. 2G and 2H, after a conductive layer 134 is formed in the openings 120, excess barrier layer 132 and excess conductive layer 134 outside of the openings 120 are removed to form conductive features 136.

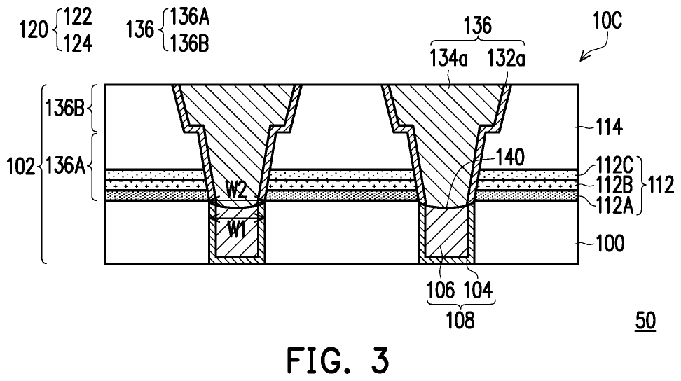

FIG. 3 is a cross-sectional view illustrating a semiconductor device 10C in accordance with some alternative embodiments of the disclosure. The semiconductor device 10C in FIG. 3 is similar to the semiconductor device 10B in FIG. 2H, so similar elements are denoted by the same reference numeral and the detailed descriptions thereof are omitted herein.

As shown in FIG. 3, the conductive features 108 may have widths W1 that is the same as or similar to widths W2 of the vias 136A of the conductive features 136. The bottom surface of the conductive layer 134a of the conductive features 136 is in physical contact with the conductive layer 106 of the conductive features 108. The barrier layer 132a of the conductive features 136 extends continuously form the sidewalls of the dielectric layer 114 to the sidewalls of the first etch stop layer 112A and is in physical contact with the barrier layer 104 of the conductive features 108.

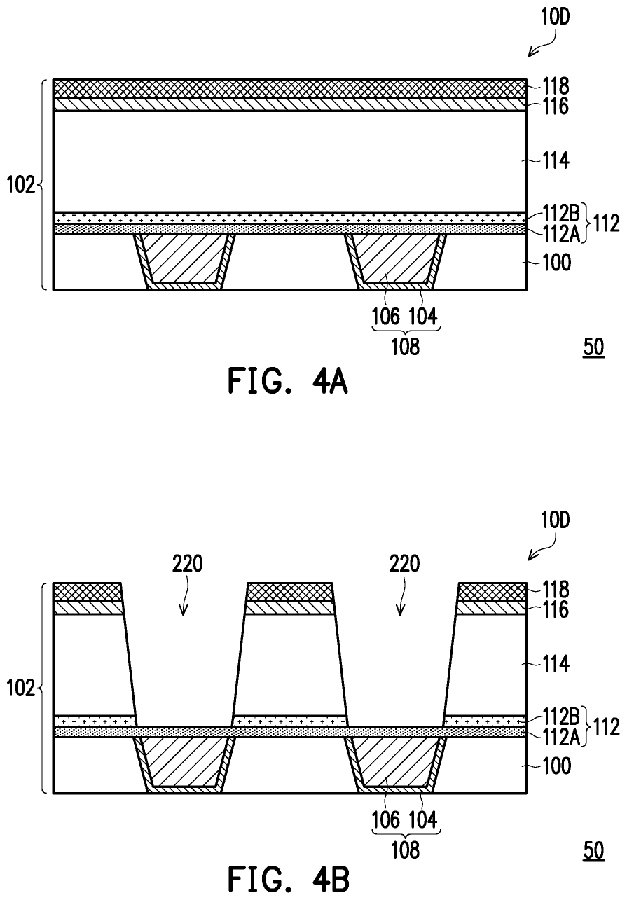

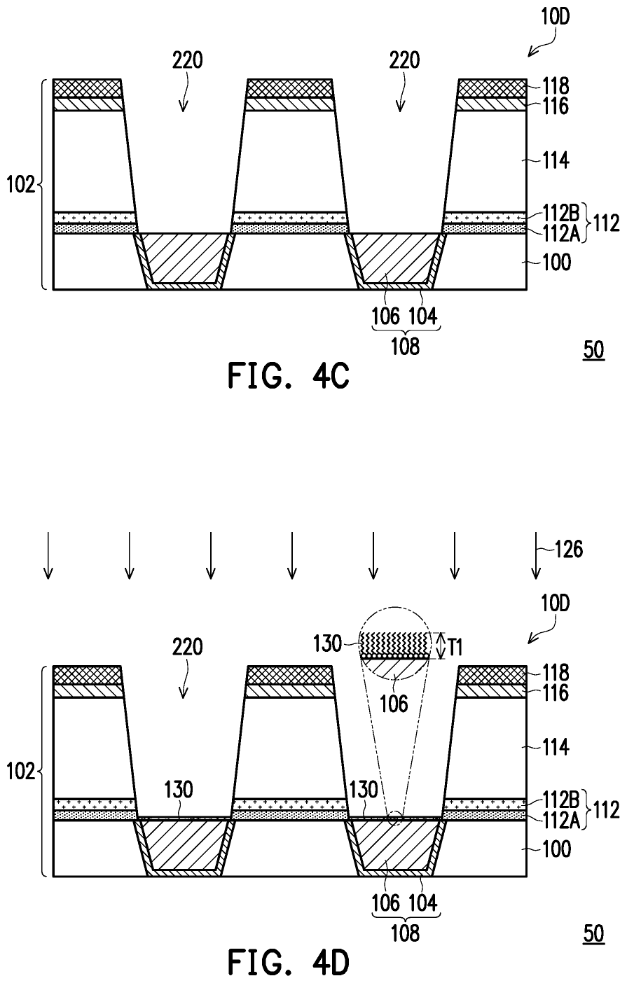

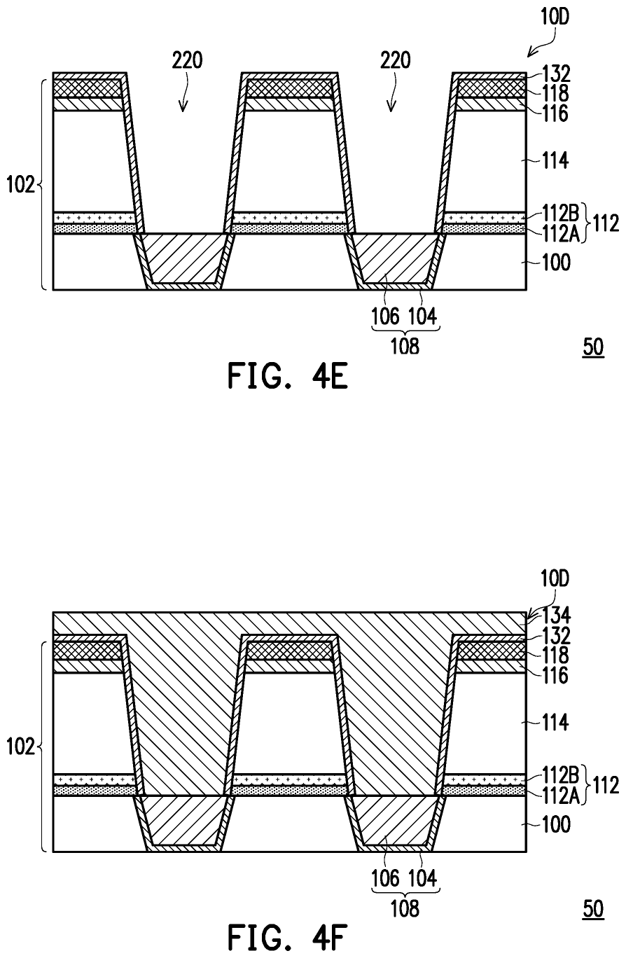

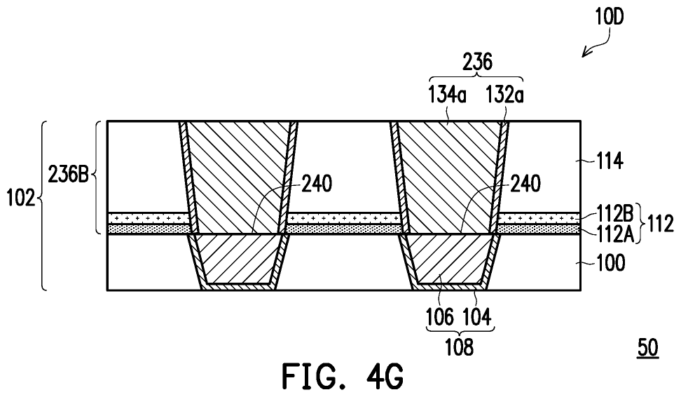

FIG. 4A to FIG. 4G are cross-sectional views illustrating various stages of a method of fabricating a semiconductor device 10D in accordance with some alternative embodiment of the disclosure. The semiconductor device 10D in FIG. 4G is similar to the semiconductor device 10A in FIG. 1D, so similar elements are denoted by the same reference numeral and the detailed descriptions thereof are omitted herein.

Referring to FIGS. 4A and 4B, after the hard mask layer 118 is formed, a patterning process may be performed to form openings 220 in the hard mask layer 118, the cap layer 116, the dielectric layer 114, and the second etch stop layer 112B by using the first second etch stop layer 112A as an etch stop layer. The openings 220 each may expose the first second etch stop layer 112A. In some embodiments, the openings 220 are single damascene openings. The single damascene openings may be trenches. The openings 220 may be formed using photolithography with masking technologies and anisotropic etch operations (e.g., plasma etching or reactive ion etching).

Referring to FIG. 4C, the first etch stop layer 112A exposed by the openings 220 is removed to expose the conductive features 108. In some embodiments, the removal of a portion of the first etch stop layer 112A is by isotropic etch operations (e.g., wet etching), although any suitable removal process may be used.

Referring to FIG. 4D, after a backing process and an active preclean process (APC) are performed, a surface treatment 126 is performed on the conductive features 108 exposed by the openings 220 to selectively modify top surfaces of the conductive features 108. In some embodiments, the surface treatment 126 is performed to provide treated surfaces of the conductive features 108 with high hydrophobicity or super hydrophobicity. The hydrophobicity of the treated surfaces of the conductive features 108 is greater than the hydrophobicity of the more hydrophobic surfaces of the first etch stop layer 112A. The surface treatment 126 may be performed by selectively forming inhibitor portions 130 on the conductive features 108 described as above.

Referring to FIG. 4E, a barrier layer 132 may be formed in the openings 220. The hydrophobicity of the high hydrophobic surfaces of the inhibitor portions 130 is greater than the hydrophobicity of the more hydrophobic surfaces of the first etch stop layer 112A, and thus the inhibitor portions 130 may prevent the barrier layer 132 from depositing on its surface, and the barrier layer 132 may be formed on the first etch stop layer 112A.

Referring to FIG. 4F and FIG. 4G, after a conductive layer 134 be formed in the openings 220, excess barrier layer 132 and excess conductive layer 134 outside of the openings 220 are removed to form conductive features 236.

The conductive features 236 are single damascene interconnects including conductive lines 236B. The sidewalls of the conductive layer 134a of the conductive lines 236B are wrapped by the barrier layer 132a. The bottoms of the conductive layer 134a of the conductive lines 236B are electrically connected to and in physical contact with the conductive features 108. Interfaces 240 between bottom surfaces of the conductive layer 134a and the top surface of the conductive feature 108 are free of the barrier layer 132a. The barrier layer 132a of the conductive features 136 extends continuously form the sidewalls of the dielectric layer 114 to the sidewalls of the first etch stop layer 112A and is in physical contact with the barrier layer 104 of the conductive features 108.

The structures of the semiconductor devices are illustrated below with reference to FIG. 1F, FIG. 2H, FIG. 3, and FIG. 4G. In some embodiments, the semiconductor device 10A, 10B, 10C, or 10D includes an interconnect structure 102. The interconnect structure 102 includes a conductive feature 108, a first etch stop layer 112A, a second etch stop layer 112B, a second dielectric layer 114, and a conductive feature 136/236. The conductive feature 108 is in the dielectric layer 100. The first etch stop layer 112A is disposed over the conductive feature 108 and the dielectric layer 100. The second etch stop layer 112B on the first etch stop layer 112A. The second dielectric layer 114 on the second etch stop layer 112B. The conductive feature 136/236 electrically connecting the conductive feature 108. The conductive feature 136/236 includes a conductive layer 134a and a barrier layer 132a. The conductive layer 134a extends through the second dielectric layer 114, the second etch stop layer 112B, and the first etch stop layer 112A to contact to the conductive feature 108. The barrier layer 132a is sandwiched between the conductive layer 134a and the second dielectric layer 114, the conductive layer 134a and the second etch stop layer 112B, and between the conductive layer 134a and the first etch stop layer 112A.

In some embodiments, the conductive feature 136/236 includes a via 136A and a conductive line 136B on the via 136A with reference to FIG. 1F, FIG. 2H, and FIG. 3.

In some embodiments, the sidewalls of the conductive layer 134a of the via 136A is separated from the first etch stop layer 112A by the barrier layer 132a with reference to FIG. 1F, FIG. 2H, and FIG. 3.

In some embodiments, the first etch stop layer 112A and the second etch stop layer 112B are formed with different materials, and the first etch stop layer 112A includes a Group IV element-doped layer. For example, the Group IV element-doped layer includes carbon-doped metal oxide, carbon-doped metal nitride, metal carbide, semiconductor carbide, semiconductor carbon nitride, semiconductor carbon oxide, or a combination thereof.

In some embodiments, a bottom surface of the conductive layer 134a of the via 136A is in physical contact with a top surface of the conductive feature 108 with reference to FIG. 1F, FIG. 2H, and FIG. 3.

In some embodiments, the conductive feature 108 includes a second conductive layer 106 and a second barrier layer 104 surrounding the second conductive layer 106. A top surface of the second conductive layer 106 of the conductive feature 108 is in contact with a bottom surface of the conductive layer 134a of the via 136A, and a top surface of the second barrier layer 104 of the conductive feature 108 is in contact with a bottom surface the barrier layer 132a of the via 136A with reference to FIG. 3.

In some embodiments, the semiconductor device further include a third etch stop layer 112C disposed between the second dielectric layer 114 and the second etch stop layer 112B with reference to FIG. 2H. The third etch stop layer 112C and the second etch stop layer 112B are formed with different materials.

The structure of the semiconductor device is illustrated below with reference to FIG. 4G. In some embodiments, the semiconductor device 10D includes an interconnect structure 102. The interconnect structure 102 includes a conductive feature 108, a dielectric layer 100, a second dielectric layer 114, an etch stop stack 112, and a conductive line 236B. The conductive feature 108 is disposed in a dielectric layer 100. The second dielectric layer 114 is disposed over the dielectric layer 100. The etch stop stack 112 is inserted between the dielectric layer 100 and the second dielectric layer 114. The conductive line 236B is disposed in the second dielectric layer 114 and the etch stop stack 112. The conductive line 236B includes a conductive layer 134a and a barrier layer 132a. The conductive layer 134a is disposed in the second dielectric layer 114 and the etch stop stack 112. The barrier layer 132a extends from a top of the second dielectric layer 114 to a bottom of the etch stop stack 112. The conductive layer 134a is laterally surrounded by the barrier layer 132a and in contact with the conductive feature 108.

In some embodiments, the barrier layer 132a separates the conductive layer 134a from the second dielectric layer 114 and the etch stop stack 112 with reference to FIG. 4G.

In some embodiments, the etch stop stack 112 includes a first etch stop layer 112A and a second etch stop layer 112B on the first etch stop layer 112A with reference to FIG. 4G.

In some embodiments, the barrier layer 132a warps sidewalls of the first etch stop layer 112A and the second etch stop layer 112B with reference to FIG. 4G.

In some embodiments, the conductive feature 108 includes a second conductive layer 106 and a second barrier layer 104 surrounding the second conductive layer 106 with reference to FIG. 4G.

In some embodiments, the second conductive layer 106 is in contact with the conductive layer 134a, and the second barrier layer 104 is in contact with the barrier layer 132a with reference to FIG. 4G.

In some embodiments, an interface 240 between a bottom surface of the conductive layer 134a and a top surface of the second conductive layer 106 is free of the barrier layer 132a with reference to FIG. 4G.

In view of above, in the method of fabricating interconnect structure of the disclosure, the bottom etch stop layer 112A of the etch stop stack 112 provide a more hydrophobic surfaces to prevent the inhibitor portion 130 forming thereon. The barrier layer 136a may be formed to wrap the entire sidewalls of the bottom etch stop layer 112A. Therefore, the barrier layer 136a can prevent metal, such as copper, of the conductive layer 134a of the interconnect from diffusing into the bottom etch stop layer 112A and the dielectric layer 114, so that the interconnect of the semiconductor device have a high stability and good adhesion to the metal of the conductive layer 134 and the dielectric layer 114.

In accordance with some embodiments of the disclosure, an interconnect structure includes a first conductive feature, a first dielectric layer, a first etch stop layer, a second etch stop layer, a second dielectric layer, and a second conductive feature. The first conductive feature formed in the first dielectric layer. The first etch stop layer is disposed over the first conductive feature and the first dielectric layer. The second etch stop layer is disposed on the first etch stop layer. The second dielectric layer is disposed on the second etch stop layer. The second conductive feature is electrically connecting the first conductive feature. The second conductive feature includes a first conductive layer and a first barrier layer. The first conductive layer extends through the second dielectric layer, the second etch stop layer, and the first etch stop layer to contact to the first conductive feature. The first barrier layer is sandwiched between the first conductive layer and the second dielectric layer, the first conductive layer and the second etch stop layer, and between the first conductive layer and the first etch stop layer.

In accordance with some alternative embodiments of the disclosure, an interconnect structure includes a conductive feature, a first dielectric layer, a second dielectric layer, an etch stop stack, and a conductive line. The conductive feature is disposed in a first dielectric layer. The second dielectric layer is disposed over the first dielectric layer. The etch stop stack is inserted between the first dielectric layer and the second dielectric layer. The conductive line is disposed in the second dielectric layer and the etch stop stack. The conductive line includes a first conductive layer and a first barrier layer. The first conductive layer is disposed in the second dielectric layer and the etch stop stack. The first barrier layer extends from a top of the second dielectric layer to a bottom of the etch stop stack. The first conductive layer is laterally surrounded by the first barrier layer and in contact with the conductive feature.

In accordance with some alternative embodiments of the disclosure, a method of forming an interconnect structure includes at least the following steps. A first conductive feature is formed in a first dielectric layer. The first dielectric layer surrounds the first conductive feature. A first etch stop layer is formed on the first conductive feature and the first dielectric layer. A second etch stop layer is formed on the first etch stop layer. A second dielectric layer is formed on the second etch stop layer. An opening is formed in the second dielectric layer, the second etch stop layer and the first etch stop layer. The opening exposes a portion of a top surface of the first conductive feature. An inhibitor portion is formed on the portion of the top surface of the first conductive feature. A barrier layer is formed on sidewalls of the second dielectric layer, the second etch stop layer and a first etch stop layer exposed by the opening. The inhibitor portion is removed. A conductive layer is filled in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnect structure, comprising:
a first conductive feature in a first dielectric layer;
a first etch stop layer over the first conductive feature and the first dielectric layer;
a second etch stop layer on the first etch stop layer;
a second dielectric layer on the second etch stop layer; and
a second conductive feature electrically connecting the first conductive feature, wherein the second conductive feature comprises;
a first conductive layer extending through the second dielectric layer, the second etch stop layer, and the first etch stop layer to contact to the first conductive feature; and
a first barrier layer sandwiched between the first conductive layer and the second dielectric layer, the first conductive layer and the second etch stop layer, and between the first conductive layer and the first etch stop layer.

2. The interconnect structure of claim 1, wherein the second conductive feature comprises a via and a conductive line on the via.

3. The interconnect structure of claim 2, wherein sidewalls of the first conductive layer of the via are separated from the first etch stop layer by the first barrier layer.

4. The interconnect structure of claim 2, wherein the first etch stop layer and the second etch stop layer have different materials, and the first etch stop layer comprises a Group IV element-doped layer.

5. The interconnect structure of claim 4, wherein a material of the Group IV element-doped layer comprises carbon-doped metal oxide, carbon-doped metal nitride, metal carbide, semiconductor carbide, semiconductor carbon nitride, semiconductor carbon oxide, or a combination thereof.

6. The interconnect structure of claim 2, wherein a bottom surface of the first conductive layer of the via is in physical contact with a top surface of the first conductive feature.

7. The interconnect structure of claim 2, wherein the first conductive feature comprises a second conductive layer and a second barrier layer surrounding the second conductive layer.

8. The interconnect structure of claim 7, wherein a top surface of the second conductive layer of the first conductive feature is in contact with a bottom surface of the first conductive layer of the via, and a top surface of the second barrier layer of the first conductive feature is in contact with a bottom surface the first barrier layer of the via.

9. The interconnect structure of claim 1, further comprising:
a third etch stop layer disposed between the second dielectric layer and the second etch stop layer, wherein the third etch stop layer and the second etch stop layer have different materials.

10. An interconnect structure, comprising:
a conductive feature disposed in a first dielectric layer;
a second dielectric layer disposed over the first dielectric layer;
an etch stop stack inserted between the first dielectric layer and the second dielectric layer;
a conductive line disposed in the second dielectric layer and the etch stop stack, wherein the conductive line comprises:
a first conductive layer disposed in the second dielectric layer and the etch stop stack
a first barrier layer extending from a top of the second dielectric layer to a bottom of the etch stop stack,
wherein the first conductive layer is laterally surrounded by the first barrier layer and in contact with the conductive feature.

11. The interconnect structure of claim 10, wherein the first barrier layer separates the first conductive layer from the second dielectric layer and the etch stop stack.

12. The interconnect structure of claim 10, wherein the etch stop stack comprises a first etch stop layer and a second etch stop layer on the first etch stop layer.

13. The interconnect structure of claim 12, wherein the first barrier layer covers sidewalls of the first etch stop layer and the second etch stop layer.

14. The interconnect structure of claim 10, wherein the conductive feature comprises a second conductive layer and a second barrier layer surrounding the second conductive layer.

15. The interconnect structure of claim 14, wherein the second conductive layer is in contact with the first conductive layer, and the second barrier layer is in contact with the first barrier layer.

16. The interconnect structure of claim 15, wherein an interface between a bottom surface of the first conductive layer and a top surface of the second conductive layer is free of the first barrier layer.

17. A method of forming an interconnect structure, comprising:
forming a first conductive feature and a first dielectric layer, wherein the first dielectric layer surrounds the first conductive feature;
forming a first etch stop layer on the first conductive feature and the first dielectric layer;
forming a second etch stop layer on the first etch stop layer;
forming a second dielectric layer on the second etch stop layer;
forming an opening in the second dielectric layer, the second etch stop layer and the first etch stop layer, wherein the opening exposes a portion of a top surface of the first conductive feature;
forming an inhibitor portion on the portion of the top surface of the first conductive feature;
forming a barrier layer on sidewalls of the second dielectric layer, the second etch stop layer and a first etch stop layer exposed by the opening;
removing the inhibitor portion; and
forming a conductive layer in the opening.

18. The method of claim 17, wherein the inhibitor portion comprises a self-assembled monolayer.

19. The method of claim 17, wherein the first etch stop layer comprises a Group IV element-doped layer.

20. The method of claim 19, wherein the Group IV element-doped layer comprises AlOₓC_{y}, AlₓC_{y}, AlₓC_{y}N_{z}, TiOₓC_{y}, TiₓC_{y}, TiₓC_{y}N_{z}, WOₓC_{y}, WₓC_{y}, WₓC_{y}N_{z}, SiOₓC_{y}, SiC, SiₓC_{y}N_{z} or a combination thereof.
